(19) United States
(12) Patent Application Publication
(10) Pub. No.: US 2023/0030843 A1
(43) Pub. Date: Feb. 2, 2023

(54) SEMICONDUCTOR STRUCTURE AND METHOD FOR MANUFACTURING THE SAME

(71) Applicant: NANYA TECHNOLOGY CORPORATION, New Taipei City (TW)

(72) Inventors: ROU-WEI WANG, TAIPEI CITY (TW); CHUN-HENG WU, TAOYUAN CITY (TW); JEN-I LAI, TAOYUAN CITY (TW)

(21) Appl. No.: 17/390,492

(22) Filed: Jul. 30, 2021

(51) Int. Cl. H01L 27/108; G11C 5/06; H01L 23/528; H01L 23/532

(52) U.S. Cl. CPC H01L 27/10885; H01L 27/10888; H01L 27/10805; G11C 5/063; H01L 23/5283; H01L 23/53266

(57) ABSTRACT

The disclosure provides a semiconductor structure comprising a plurality of bit line structures and a method for manufacturing the same. In the present disclosure, by allowing at least one of the bit line structures to have a width at its top less than a width at its bottom, the semiconductor structure may have an increased total tungsten volume. The contact surface between the bit line structures and the landing pad is increased, so the landing pad resistance can be decreased. Therefore, the performance of the semiconductor structure can be enhanced.

### TECHNICAL FIELD

The present disclosure relates to a semiconductor structure and a method for manufacturing the same, and more particularly, to a semiconductor structure with a plurality of bit line structures in which at least one of the bit line structures has a width at its top less than a width at its bottom, and a method for preparing the same.

### DISCUSSION OF THE BACKGROUND

Dynamic random-access memory (DRAM) is a widely used type of integrated circuit device that plays an indispensable role in the electronic industry. A conventional DRAM cell consists of a transistor and a capacitor. The transistor includes a source, a drain and a gate. The source of the transistor is connected to a corresponding bit line. The drain of the transistor is connected to a storage electrode of the capacitor. The gate of the transistor is connected to a corresponding word line. An opposite electrode of the capacitor is biased with a constant voltage source. A landing pad is formed for a purpose of electrical interconnection.

With advancing miniaturization and integration requirements of semiconductor devices, semiconductor structures and features of DRAM cells become more miniaturized as well. Accordingly, the continual reduction in semiconductor structure and feature sizes places ever-greater demands on techniques used to form the semiconductor structures and features. As densities of DRAM cells increase to levels greater than 1 billion bytes per cell, areas allotted for the DRAM capacitor structure have been decreased. Smaller capacitor structures, presenting decreased capacitor surface area, can result in decreases in DRAM capacitance, and thus in decreased DRAM performance. In addition, as the DRAM cells become smaller, the highly compact structures of the DRAM cells result in high parasitic capacitance between a bit line and a cell plate of a trench capacitor of the DRAM cell, thereby causing parasitic leakage. Accordingly, there is a continuous need to improve manufacturing processes of semiconductor structures so that such problems can be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method of manufacturing a semiconductor structure. The method comprises: providing a substrate having a plurality of bit line structures; sequentially depositing a polysilicon layer and a cobalt silicide layer on the substrate wherein the plurality of bit line structures penetrate through the polysilicon layer and protrude from the cobalt silicide layer; anisotropically etching the plurality of bit line structures to remove a portion of a top of at least one of the bit line structures; conformally depositing a titanium nitride layer on the cobalt silicide layer and the plurality of bit line structures; depositing a first tungsten layer on the titanium nitride layer; performing a chemical mechanical polishing to remove a portion of the titanium nitride layer and a portion of the top of at least one of the bit line structures so as to form a substantially flat horizontal surface, wherein at least one of the bit line structures has a width at its top less than a width at its bottom; depositing a second tungsten layer on the first tungsten layer; etching the second tungsten layer to form a recess wherein a top corner of the bit line structure is removed; and depositing a land pad which fills the recess and covers a portion of the second tungsten layer around the recess.

In some embodiments, the step of providing a substrate having a plurality of bit line structures is performed by sequentially stacking a metal nitride layer, a bit line layer, and a hard mask layer for forming at least one of the bit line structures on the substrate.

In some embodiments, the step of providing a substrate having a plurality of bit line structures is performed by sequentially stacking a titanium nitride layer, a bit line layer, and a silicon nitride layer for forming at least one of the bit line structures on the substrate.

In some embodiments, the step of sequentially depositing a polysilicon layer and a cobalt silicide layer on the substrate is performed by spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof.

In some embodiments, the step of anisotropically etching the plurality of bit line structures to remove a portion of a top of at least one of the bit line structures is performed by anisotropically etching the silicon nitride layer of at least one of the bit line structures in the presence of a fluorine-containing compound at a temperature between 10° C. and 200° C. and a pressure between 0.1 and 30 torr.

In some embodiments, the step of anisotropically etching the plurality of bit line structures to remove a portion of a top of at least one of the bit line structures is performed by: forming a resist layer on the cobalt silicide layer, wherein the resist layer fills the space between two adjacent bit line structures; etching back the resist layer to reveal the silicon nitride layer of the bit line structure; anisotropically etching the silicon nitride layer of at least one of the bit line structures in the presence of a fluorine-containing compound at a temperature between 10° C. and 200° C. and a pressure between 0.1 and 30 torr; and removing the remaining resist layer by dry stripping or wet stripping.

In some embodiments, the fluorine-containing compound is selected from a group consisting of hydrogen fluoride, trifluoromethane, tetrafluoromethane, and sulfur hexafluoride.

In some embodiments, after the step of performing a chemical mechanical polishing, at least one of the bit line structures has a width at its top that is 20% less than a width at its bottom.

In some embodiments, after the step of performing a chemical mechanical polishing, at least one of the bit line structures has a width at its top that is 30% less than a width at its bottom.

In some embodiments, after the step of performing a chemical mechanical polishing, at least one of the bit line structures has a width at its top that is 40% less than a width at its bottom.

In some embodiments, the method further comprises performing a post-cleaning operation prior to the step of conformally depositing a titanium nitride layer on the cobalt silicide layer and the plurality of bit line structures.

In some embodiments, the step of etching the second tungsten layer to form a recess is performed by removing a top corner of the bit line structure, a portion of the titanium nitride layer adjacent to the bit line structure, a portion of the first tungsten layer adjacent to the titanium nitride layer, and a portion of the second tungsten layer atop the first tungsten layer, the titanium nitride layer, and the bit line structure.

In some embodiments, a tilt dry-etching is performed to remove a top corner of the bit line structure.

In some embodiments, the step of depositing a land pad is performed by spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof.

Another aspect of the present disclosure provides a semiconductor structure. The semiconductor structure includes: a substrate having a plurality of bit line contacts and a plurality of carbon-carbon contacts; a plurality of bit line structures, which are disposed on a bit line contact and protruding from the substrate; a polysilicon layer, disposed on the plurality of carbon-carbon contacts of the substrate; a cobalt silicide layer, disposed on the polysilicon layer, wherein the plurality of bit line structures penetrate through the polysilicon layer and protrude from the cobalt silicide layer; a titanium nitride layer, conformally disposed on the cobalt silicide layer and the plurality of bit line structures; a first tungsten layer, disposed on the titanium nitride layer; a second tungsten layer, disposed on the first tungsten layer; and a landing pad, disposed in a top corner of the bit line structure and on a portion of the second tungsten layer; wherein at least one of the bit line structures has a width at its top less than a width at its bottom.

In some embodiments, at least one of the bit line structures includes a metal nitride layer, a bit line layer, and a hard mask layer sequentially stacked on the substrate.

In some embodiments, at least one of the bit line structures includes a titanium nitride layer, a bit line layer, and a silicon nitride layer sequentially stacked on the substrate.

In some embodiments, at least one of the bit line structures has a width at its top that is 20% less than a width at its bottom.

In some embodiments, at least one of the bit line structures has a width at its top that is 30% less than a width at its bottom.

In some embodiments, at least one of the bit line structures has a width at its top that is 40% less than a width at its bottom.

In the present disclosure, by allowing at least one of the bit line structures to have a width at its top less than a width at its bottom, the semiconductor structure may have an increased total tungsten volume. The contact surface between the bit line structures and the landing pad is increased, so the landing pad resistance can be decreased. Therefore, the performance of the semiconductor structure can be enhanced.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a representative flow diagram illustrating a method of manufacturing a semiconductor structure according to an embodiment of the present disclosure.

FIG. 2 is a cross-sectional view showing the semiconductor structure during the performing of step 101 in FIG. 1.

FIG. 3 is a cross-sectional view showing the semiconductor structure during the performing of step 103 in FIG. 1.

FIG. 4 is a cross-sectional view showing the semiconductor structure after the performing of step 103 in FIG. 1.

FIG. 5 is a cross-sectional view showing the semiconductor structure after the performing of step 105 in FIG. 1 according to a first embodiment of the present disclosure.

FIG. 6 is a cross-sectional view showing the semiconductor structure after the performing of step 107 in FIG. 1 according to the first embodiment of the present disclosure.

FIG. 7 is a cross-sectional view showing the semiconductor structure after the performing of step 109 in FIG. 1 according to the first embodiment of the present disclosure.

FIG. 8 is a cross-sectional view showing the semiconductor structure after the performing of step 111 in FIG. 1 according to the first embodiment of the present disclosure.

FIG. 9 is a cross-sectional view showing the semiconductor structure after the performing of step 113 in FIG. 1 according to the first embodiment of the present disclosure.

FIG. 10 is a cross-sectional view showing the semiconductor structure after the performing of step 115 in FIG. 1 according to the first embodiment of the present disclosure.

FIG. 11 is a cross-sectional view showing the semiconductor structure after the performing of step 117 in FIG. 1 according to the first embodiment of the present disclosure.

FIG. 12 is a cross-sectional view showing the semiconductor structure after the performing of step 105 in FIG. 1 according to a second embodiment of the present disclosure.

FIG. 13 is a cross-sectional view showing the semiconductor structure after the performing of step 107 in FIG. 1 according to the second embodiment of the present disclosure.

FIG. 14 is a cross-sectional view showing the semiconductor structure after the performing of step 109 in FIG. 1 according to the second embodiment of the present disclosure.

FIG. 15 is a cross-sectional view showing the semiconductor structure after the performing of step 111 in FIG. 1 according to the second embodiment of the present disclosure.

FIG. 16 is a cross-sectional view showing the semiconductor structure after the performing of step 113 in FIG. 1 according to the second embodiment of the present disclosure.

FIG. 17 is a cross-sectional view showing the semiconductor structure after the performing of step 115 in FIG. 1 according to the second embodiment of the present disclosure.

FIG. 18 is a cross-sectional view showing the semiconductor structure after the performing of step 117 in FIG. 1 according to the second embodiment of the present disclosure.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, descriptions of many conventional steps will be provided only briefly herein or will be omitted entirely without providing the well-known process details.

Embodiments (or examples) of the disclosure illustrated in the drawings are now described using specific language. It shall be understood that no limitation to the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, is third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure will be described in detail with reference to the accompanying drawings with numbered elements. It should be noted that the drawings are in greatly simplified form and are not drawn to scale. Moreover, dimensions have been exaggerated in order to provide a clear illustration and understanding of the present invention.

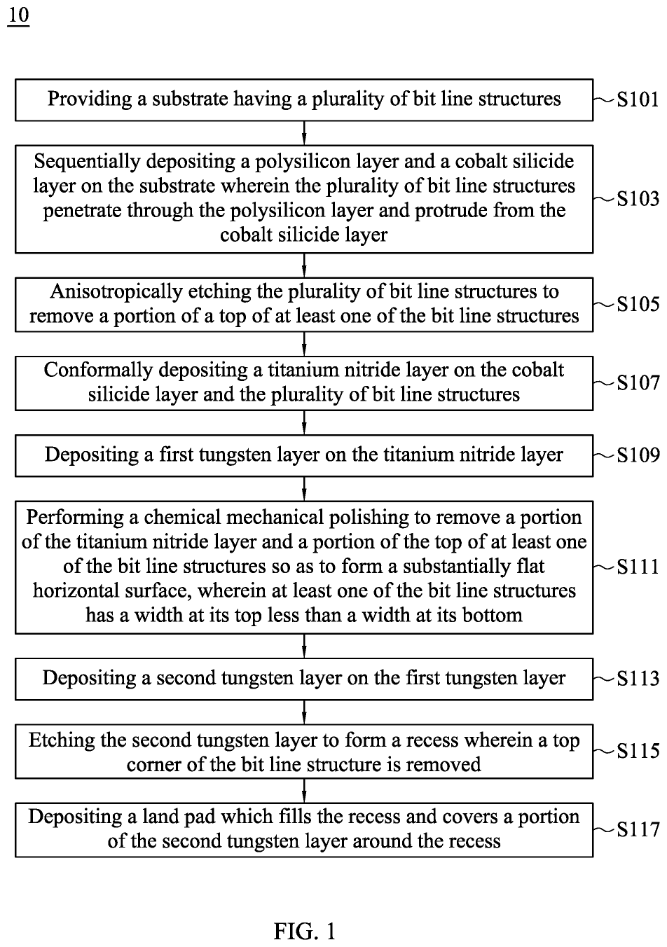

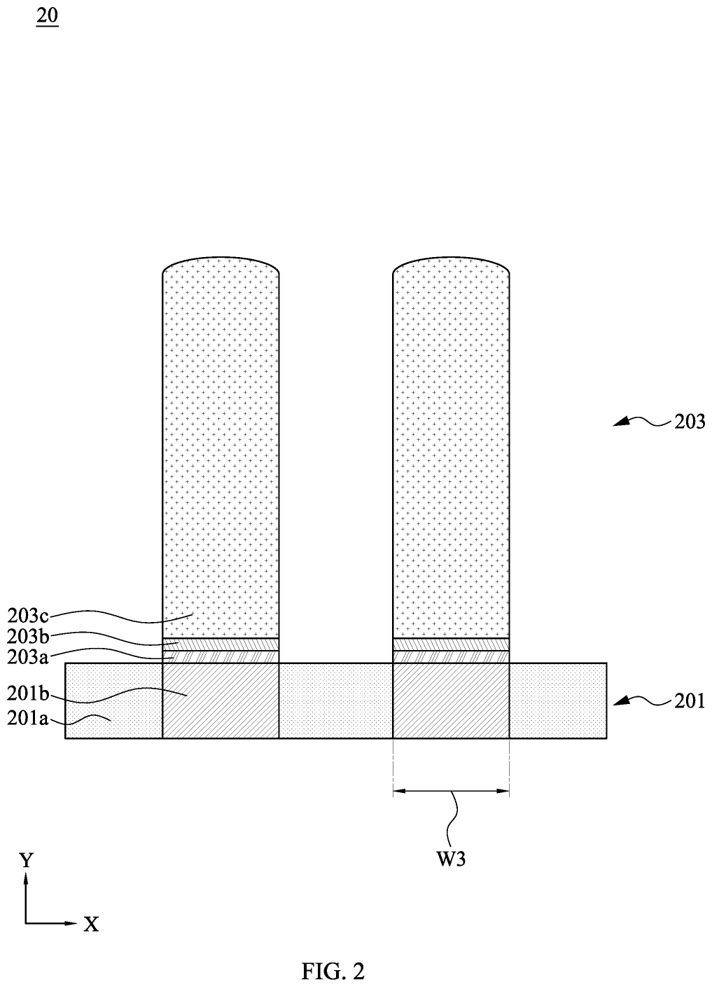

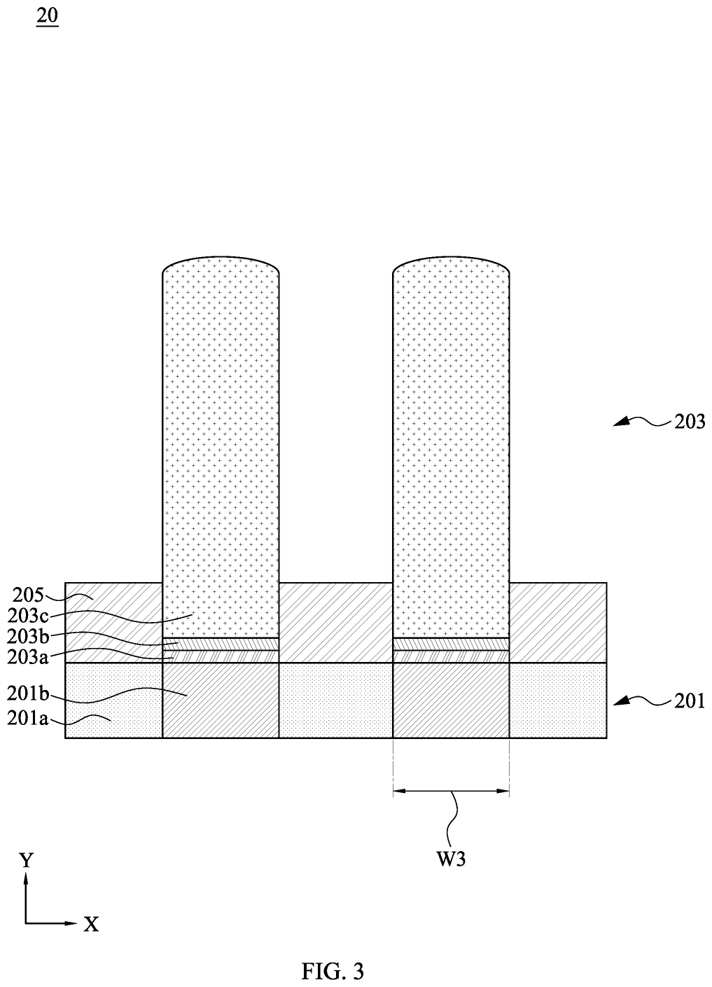

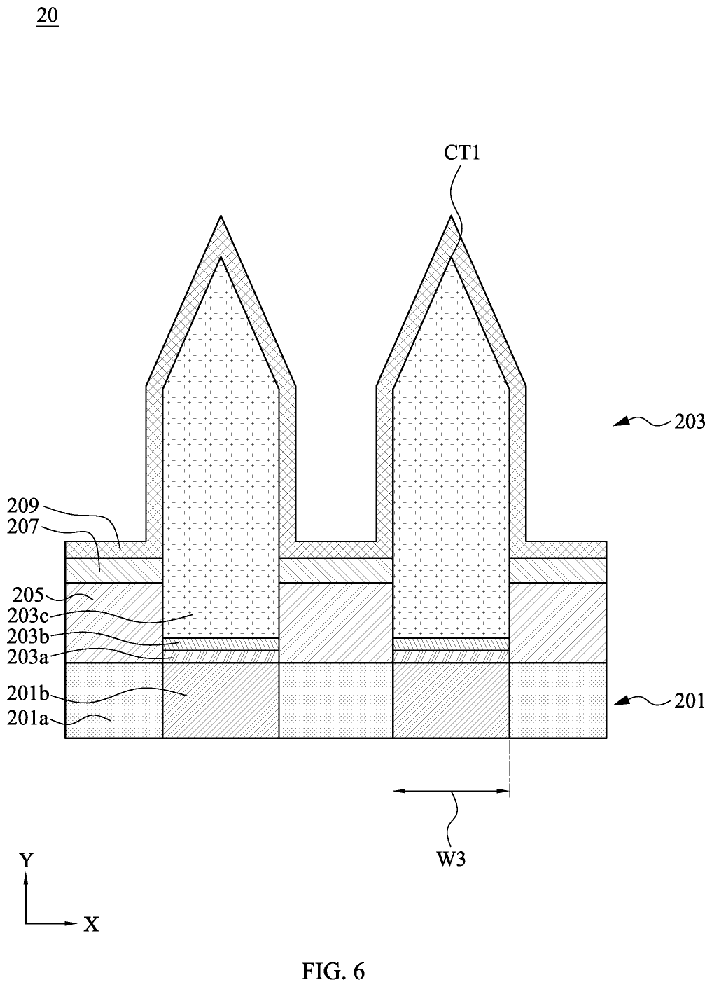

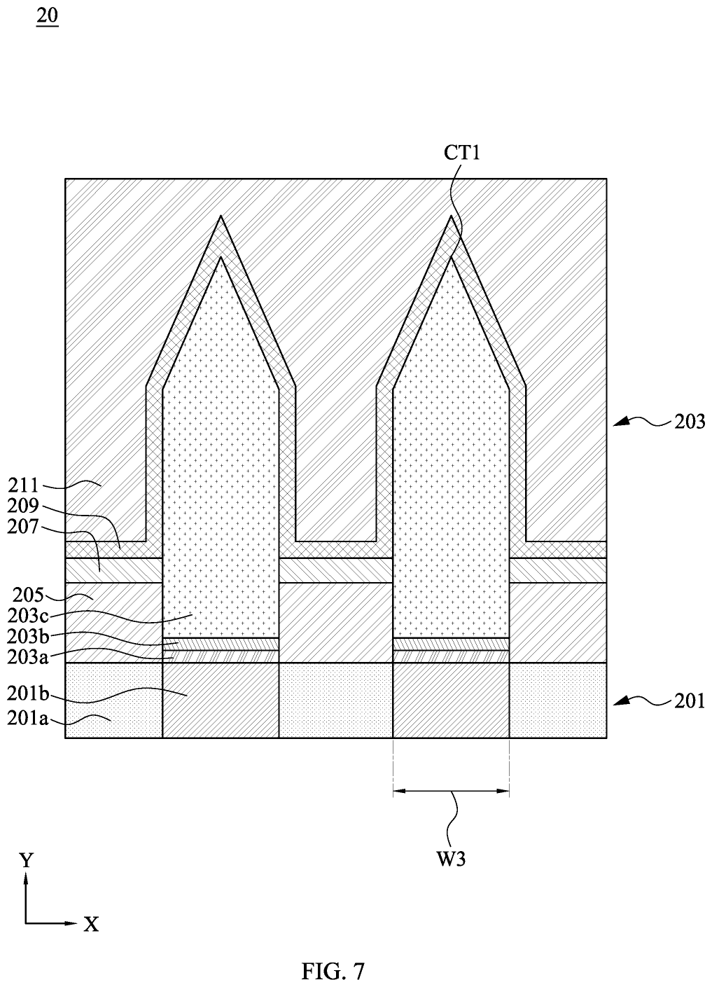

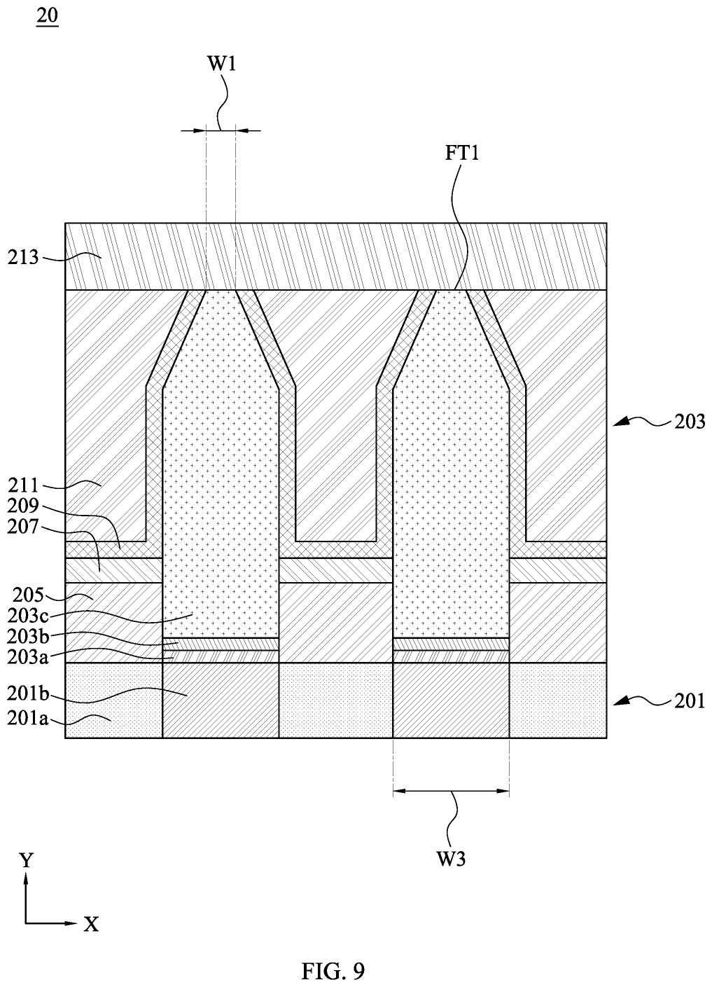

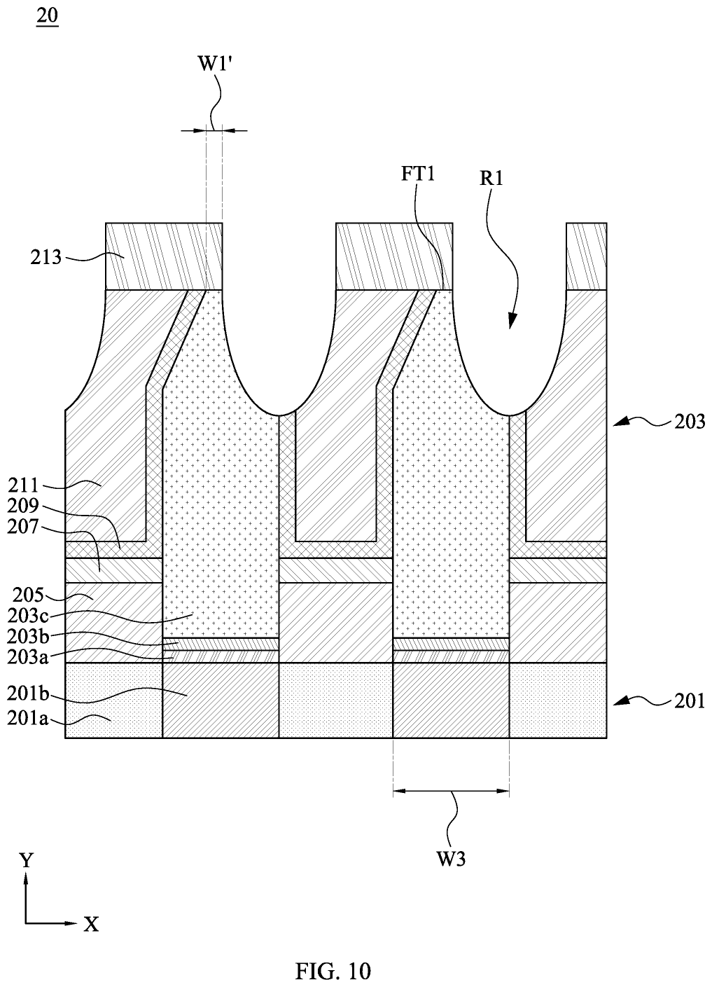

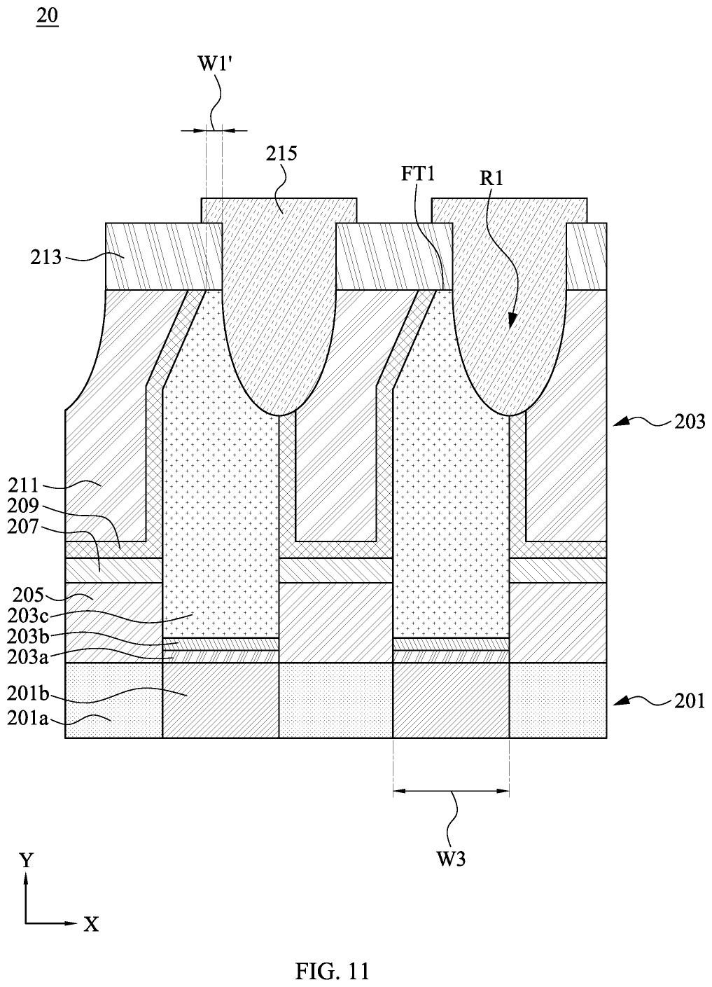

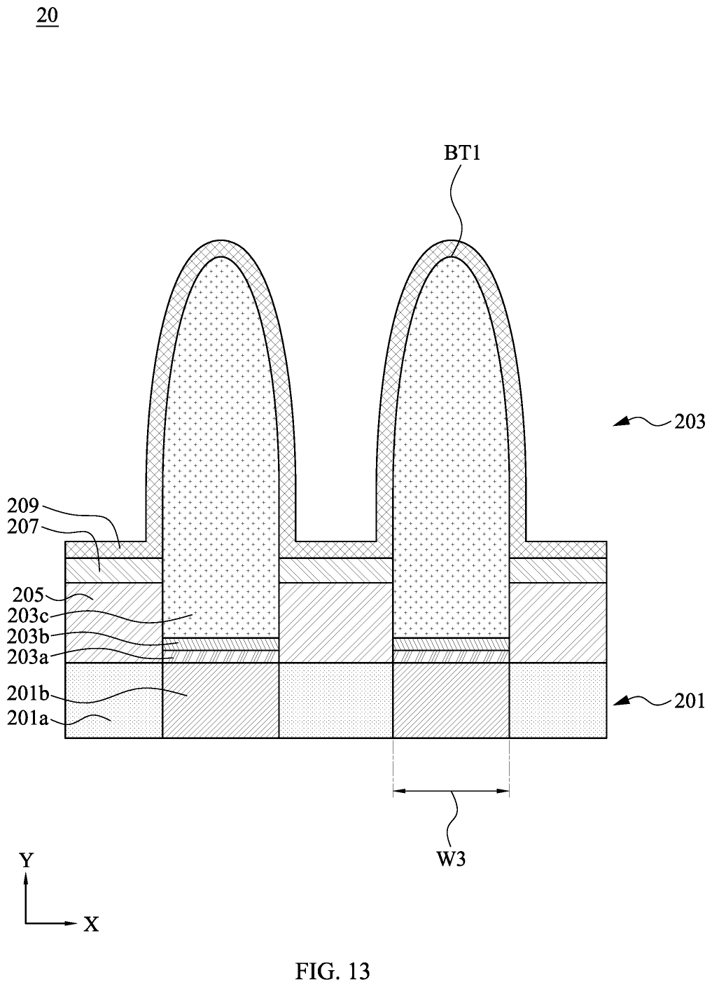

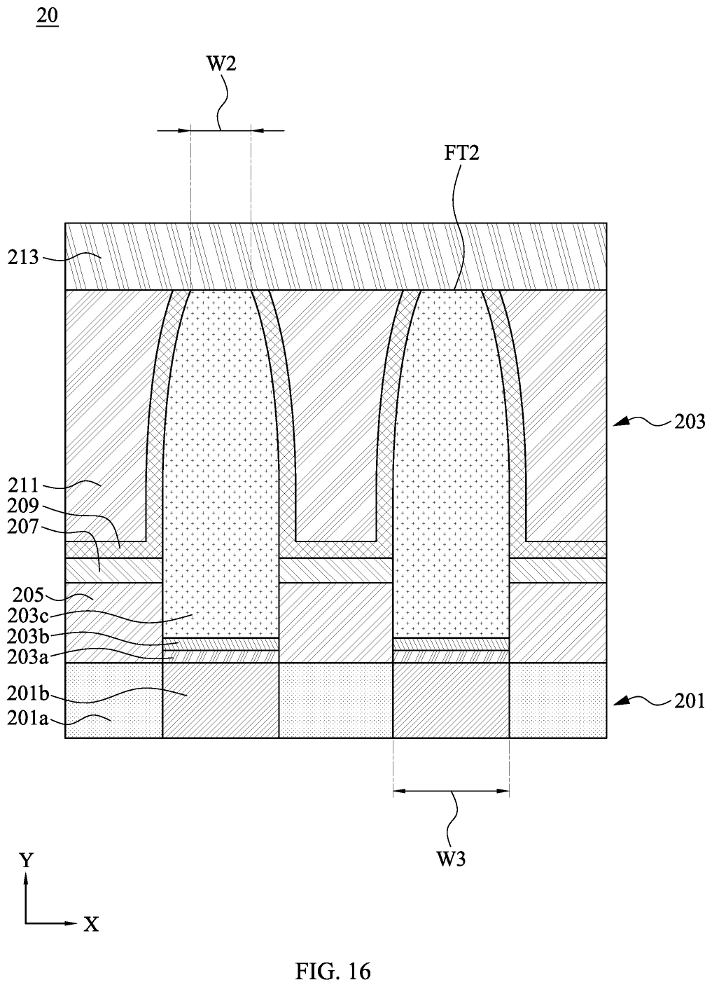

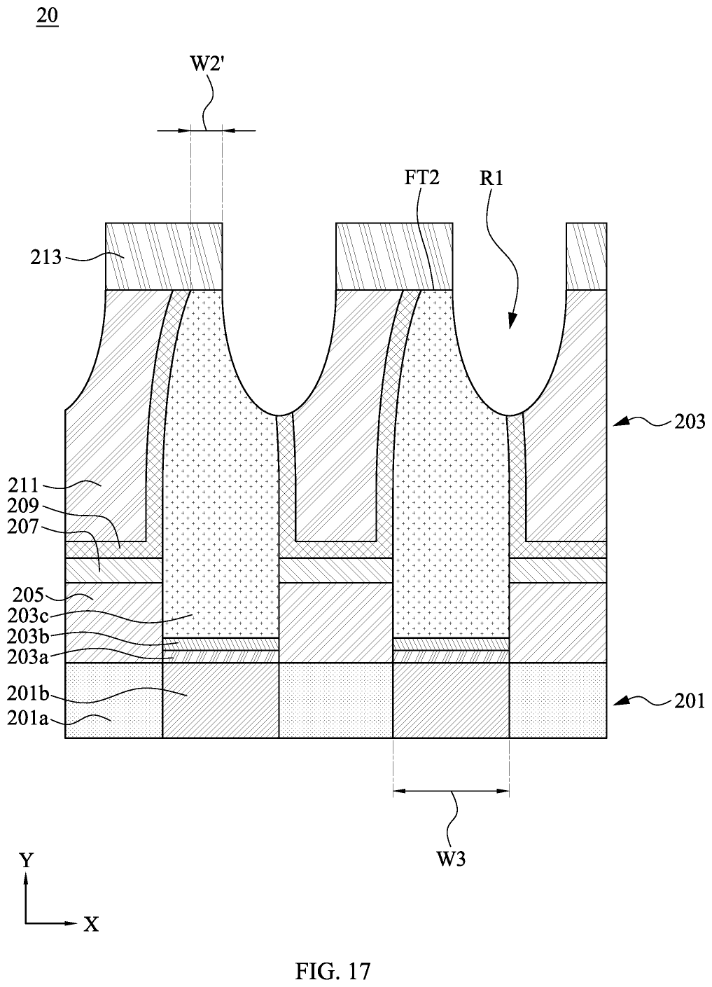

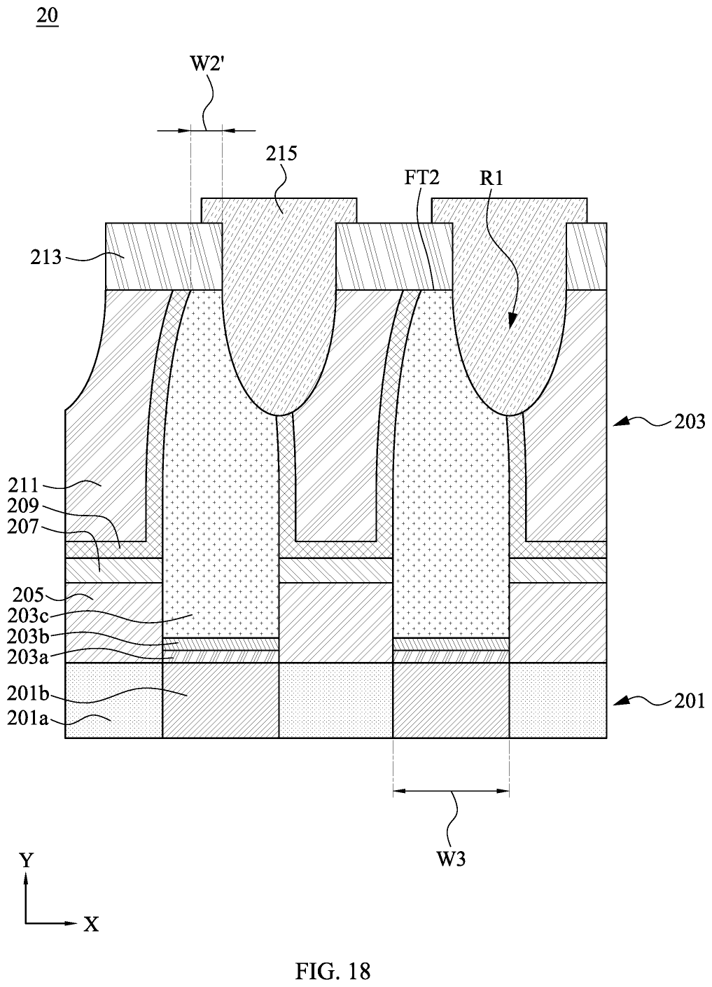

FIG. 1 is a representative flow diagram of a method 10 of manufacturing a semiconductor structure 20 according to an embodiment of the present disclosure. FIGS. 2, 3, 4, 5, 6, 7, 8, 9, 10, 11, 12, 13, 14, 15, 16, 17 and 18 are illustrative cross-sectional views showing a semiconductor structure after steps of the method are performed in accordance with some embodiments of the present disclosure.

Referring to FIGS. 1 and 2, a semiconductor substrate 201 having a plurality of bit line structures 203 is provided in step S101. In the present disclosure, the term “substrate” means and includes a base material or construction upon which materials are formed. It will be appreciated that the substrate may include a single material, a plurality of layers of different materials, a layer or layers having regions of different materials or different structures in them, or another similar arrangement. These materials may include semiconductors, insulators, conductors, or combinations thereof. For example, the semiconductor substrate 201 may be a semiconductor substrate, a base semiconductor layer on a supporting structure, a metal electrode, or a semiconductor substrate having one or more layers, structures or regions formed thereon. The semiconductor substrate 201 may be a conventional silicon substrate or other bulk substrate including a layer of semiconductive material. In some embodiments, the semiconductor substrate 201 may be a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a III-V compound semiconductor, a combination thereof, or the like.

In accordance with some embodiments of the present disclosure, as shown in FIG. 2, the bit line structure 203 may include a metal nitride layer 203a, a bit line layer 203b, and a hard mask layer 203c sequentially stacked on the substrate. The metal nitride layer 203a may be, for example, a titanium nitride layer. The hard mask layer 230c may be, for example, a silicon nitride layer. In some embodiments, prior to the formation of the metal nitride layer 203a, the substrate 203 may be subjected to a pre-metal cleaning operation. Further, in some embodiments, the substrate 203 may be subjected to a post-metal cleaning operation after the formation of the metal nitride layer 203a. Other cleaning operations or sub-operations can be optionally applied, and are not limited herein.

The plurality of bit line structures 203 can be the same or different. In some embodiments, there is no recessed portion formed adjacent to the bit line structure 203 (see FIG. 2). In some embodiments, there are recessed portions (not shown) formed adjacent to the bit line structure 203. Details of arrangement of stacked materials of the bit line structures 203 are not limited herein and can be adjusted according to different applications.

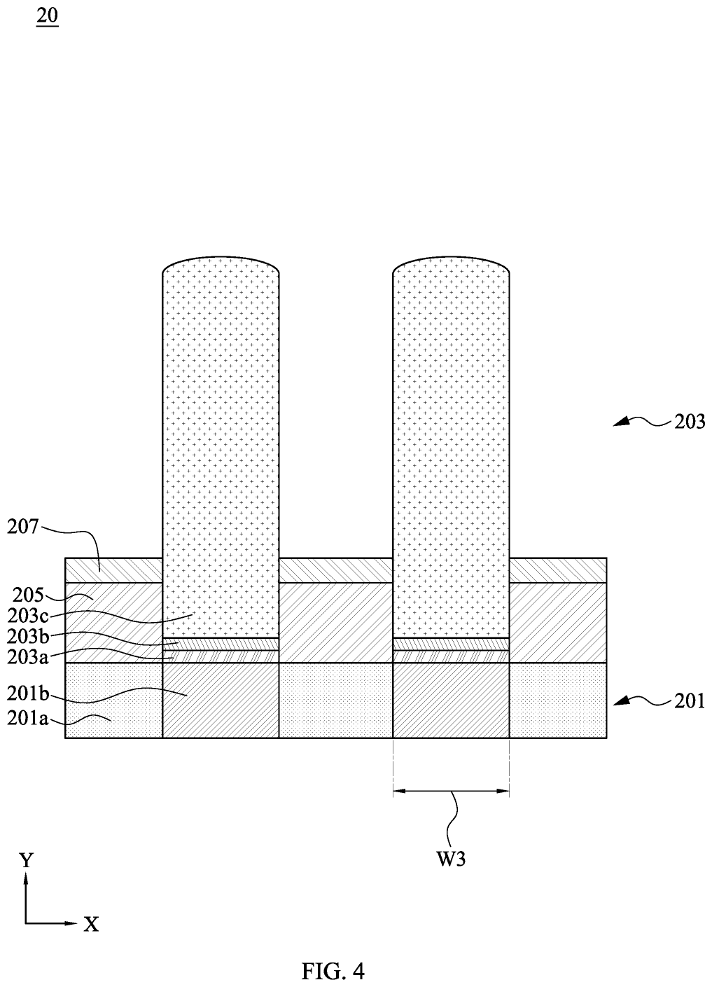

Referring to FIGS. 1, 3 and 4, in step S103, a polysilicon layer 205 and a cobalt silicide layer 207 are sequentially deposited on the semiconductor substrate 201. A process such as spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof can be used for the performing of step S103. According to a preferred embodiment of the present disclosure, step S103 is performed using ALD. Moreover, as shown in FIG. 4, the plurality of bit line structures 203 penetrate through the polysilicon layer 205 and protrude from the cobalt silicide layer 207.

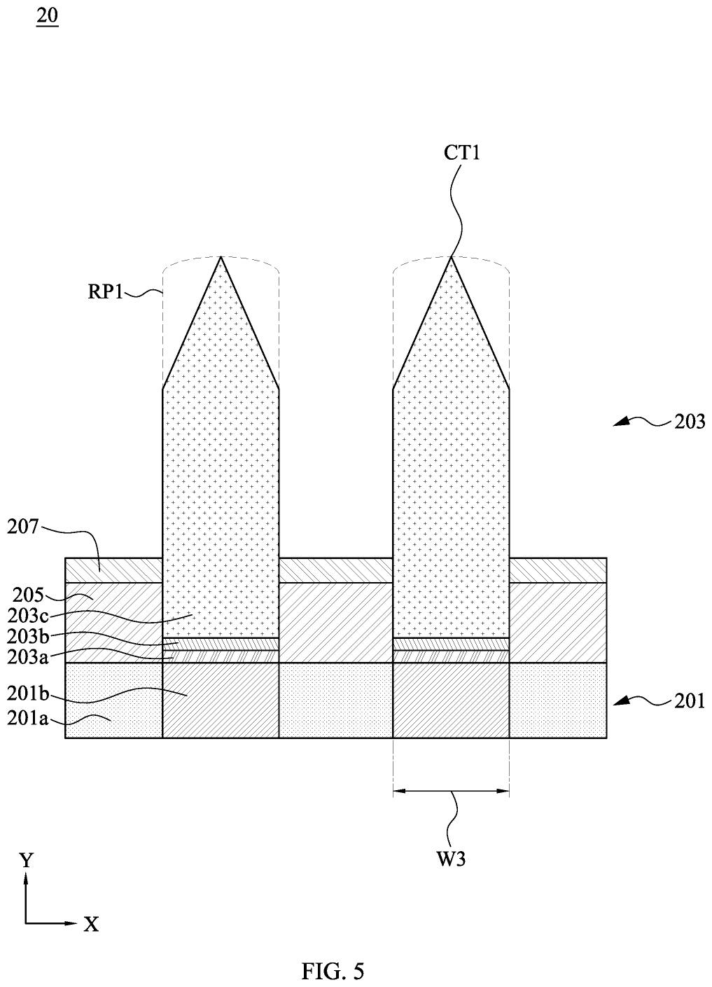

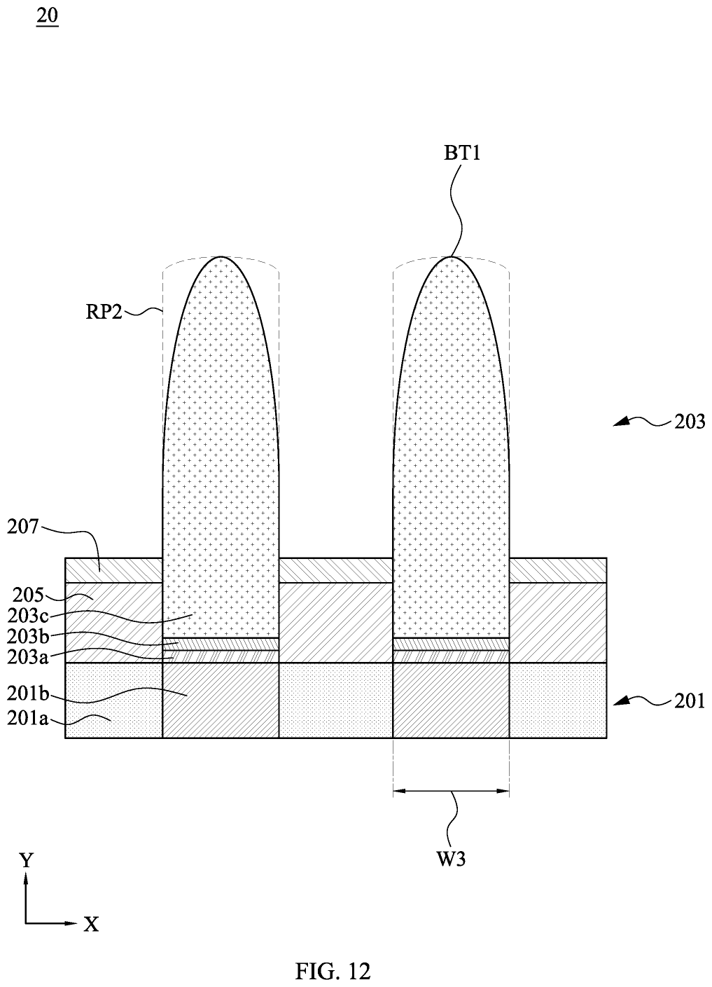

Referring to FIGS. 1, 5 and 12, in step S105, the plurality of bit line structures 203 are anisotropically etched so that a portion (i.e., RP1 in FIG. 5 or RP2 in FIG. 12) of a top of at least one of the bit line structures 203 is removed.

In a first embodiment according to the present disclosure, the step of anisotropically etching the plurality of bit line structures 203 is performed by anisotropically etching the silicon nitride layer 203c of at least one of the bit line structures 203 in the presence of a fluorine-containing compound at a temperature between 10° C. and 200° C. and a pressure between 0.1 and 30 torr. As shown in FIG. 5, in the first embodiment according to the present disclosure, at least one of the bit line structures 203 has a conical top CT1.

In a second embodiment according to the present disclosure, the step of anisotropically etching the plurality of bit line structures 203 is performed by: forming a resist layer (not shown) on the cobalt silicide layer 207 wherein the resist layer fills the space between two adjacent bit line structures 203, etching back the resist layer to reveal the silicon nitride layer 203c of the bit line structure 203, anisotropically etching the silicon nitride layer 203c of at least one of the bit line structures 203 in the presence of a fluorine-containing compound at a temperature between 10° C. and 200° C. and a pressure between 0.1 and 30 torr, and removing the remaining resist layer by dry stripping or wet stripping. As shown in FIG. 12, in the second embodiment according to the present disclosure, at least one of the bit line structures 203 has a bullet-like top BT1. In some embodiments, the fluorine-containing compound is selected from a group consisting of hydrogen fluoride, trifluoromethane, tetrafluoromethane, and sulfur hexafluoride. In a preferred embodiment of the present disclosure, the fluorine-containing compound is hydrogen fluoride. In some embodiments, after the performing of step S105, a bit line structure 203 having a dome top, a bullet-like top, a conical top or a pointed top is obtained.

Referring to FIGS. 1, 6 and 13, in step S107, a first titanium nitride layer 209 is conformally deposited on the cobalt silicide layer 207 and the plurality of bit line structures 203. A process such as spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof can be used for the performing of step S107. According to a preferred embodiment of the present disclosure, step S107 is performed using ALCVD or LPCVD.

In some embodiments, a post-cleaning operation may be performed prior to the performing of step S107. Any conventional cleaning methods are applicable to carry out the post-cleaning operation. For example, a cleaning process using a reducing agent selected from titanium tetrachloride, tantalum tetrachloride, or a combination thereof may be optionally performed.

Referring to FIGS. 1, 7 and 14, in step S109, a first tungsten layer 211 is deposited on the titanium nitride layer 209. A process such as spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof can be used for the performing of step S109. According to a preferred embodiment of the present disclosure, step S109 is performed using ALCVD or LPCVD.

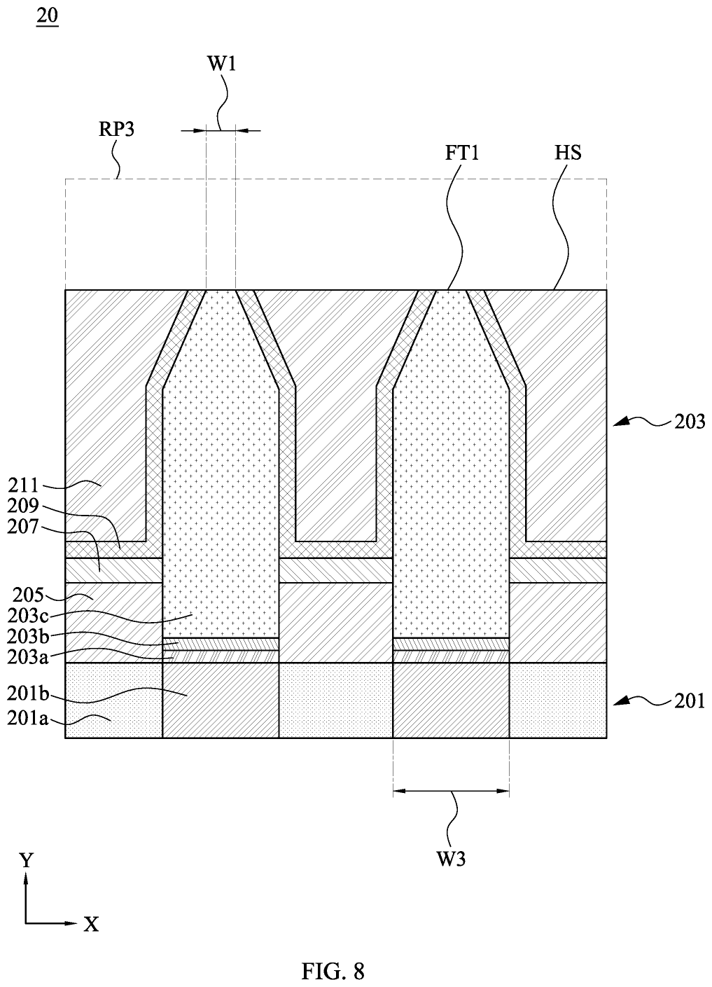

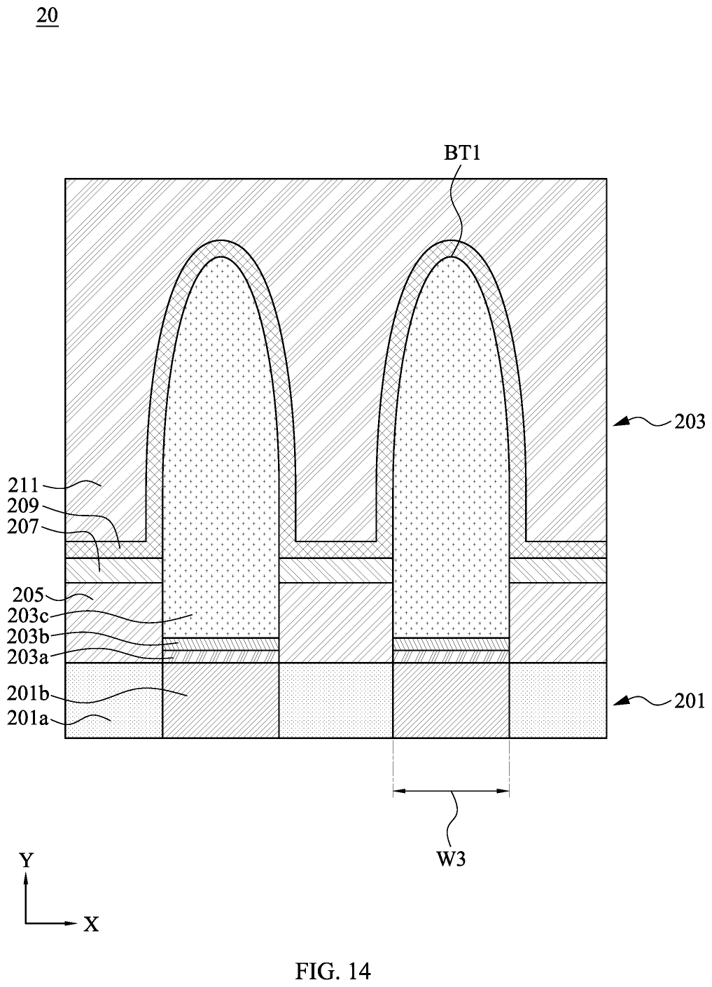

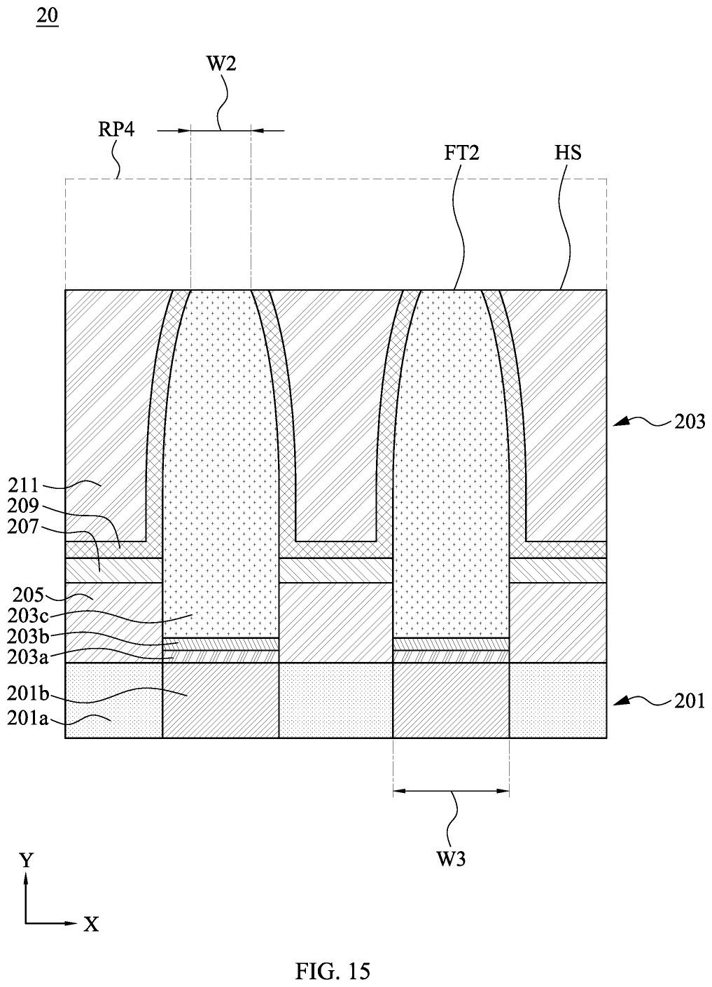

Referring to FIGS. 1, 8 and 15, in step S111, a chemical mechanical polishing is performed to remove a portion of the titanium nitride layer 209 and a portion of the top of at least one of the bit line structures 203 so as to form a substantially flat horizontal surface HS. The overall removed portion is referred by symbol RP3 in FIG. 8 or symbol RP4 in FIG. 15. The term “horizontal” as used herein refers to a direction along the X direction. As shown in FIG. 8, after the performing of step S111, at least one of the bit line structures 203 has a flat top FT1. A width W1 of the flat top FT1 of the bit line structure 203 is less than a width W3 of a bottom BT of the bit line structure 203. As shown in FIG. 14, after the performing of step S111, at least one of the bit line structures 203 has a flat top FT2. A width W2 of the flat top FT2 of the bit line structure 203 is also less than the width W3 of a bottom BT of the bit line structure 203. In some embodiments, after the step of performing a chemical mechanical polishing, at least one of the bit line structures 203 has a width at its top W1 or W2 that is 20% less than a width at its bottom W3. Preferably, after the step of performing a chemical mechanical polishing, at least one of the bit line structures 203 has a width at its top W1 or W2 that is 30% less than a width at its bottom W3. More preferably, after the step of performing a chemical mechanical polishing, at least one of the bit line structures 203 has a width at its top W1 or W2 that is 40% less than a width at its bottom W3.

Referring to FIGS. 1, 9 and 16, in step S113, a second tungsten layer 213 is deposited on the first tungsten layer 211. A process such as spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof can be used for the performing of step S113. According to a preferred embodiment of the present disclosure, step S113 is performed using PVD.

Referring to FIGS. 1, 10 and 17, in step S115, the second tungsten layer 213 is etched to form an opening and is continuously etched back to form a recess R1. A top corner of the bit line structure 203, a portion of the titanium nitride layer 209 adjacent to the top corner of the bit line structure 203, a portion of the first tungsten layer 211 adjacent to the portion of the titanium nitride layer 209, and a portion of the second tungsten layer 213 (atop the first tungsten layer 211, the titanium nitride layer 209 and the bit line structure 203) are removed. In some embodiments, the top corner of the bit line structure 203 is removed by a tilt dry-etching operation. In some embodiments, after the step of etching the second tungsten layer 213 to form a recess R1, at least one of the bit line structures 203 has a width at its top W1′ or W2′ less than a width at its bottom W3.

Referring to FIGS. 1, 11 and 18, in step S117, a landing pad 215 is deposited to fill the recess R1 and to cover a portion of the second tungsten layer 213 around the recess R1. A process such as spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof can be used for the performing of step S117. According to a preferred embodiment of the present disclosure, step S117 is performed using ALD.

In the present disclosure, by allowing at least one of the bit line structures to have a width at its top less than a width at its bottom, the semiconductor structure may have an increased total tungsten volume.

The contact surface between the bit line structures and the landing pad is increased, so the landing pad resistance can be decreased. Therefore, the performance of the semiconductor structure can be enhanced.

Although the present disclosure and its advantages have been described in detail, it should be understood that the preceding examples are included to demonstrate specific embodiments of the present disclosure. It should be appreciated by those of skill in the art that the techniques disclosed in the examples which follow represent techniques discovered by the inventors to function well in the practice of the present disclosure, and thus can be considered to constitute preferred modes for its practice. However, it should also be understood that the present disclosure is not intended to be limited to the particular forms disclosed. Rather, the different aspects of the disclosed process may be utilized in various combinations and/or independently. Thus, the present disclosure is not limited to only those combinations shown herein, but rather may include other combinations. Further, those of skill in the art should, in light of the present disclosure, appreciate that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

1. A method of manufacturing a semiconductor structure, comprising:
providing a substrate having a plurality of bit line structures;
sequentially depositing a polysilicon layer and a cobalt silicide layer on the substrate, wherein the plurality of bit line structures penetrate through the polysilicon layer and protrude from the cobalt silicide layer;
anisotropically etching the plurality of bit line structures to remove a portion of a top of at least one of the bit line structures;
conformally depositing a titanium nitride layer on the cobalt silicide layer and the plurality of bit line structures;
forming a first tungsten layer on the titanium nitride layer;
removing a portion of the titanium nitride layer and a portion of the top of at least one of the bit line structures so as to form a substantially flat horizontal surface, wherein at least one of the bit line structures has a width at its top less than a width at its bottom;
forming a second tungsten layer on the first tungsten layer;
forming a recess in a top corner of the bit line structure; and
forming a land pad which fills the recess and covers a portion of the second tungsten layer around the recess.

2. The method according to claim 1, wherein the step of providing a substrate having a plurality of bit line structures is performed by sequentially stacking a metal nitride layer, a bit line layer, and a hard mask layer for forming at least one of the bit line structures on the substrate.

3. The method according to claim 2, wherein the metal nitride layer is a titanium nitride layer, and the hard mask layer is a silicon nitride layer.

4. The method according to claim 1, wherein the step of sequentially depositing a polysilicon layer and a cobalt silicide layer on the substrate is performed by spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof.

5. The method according to claim 1, wherein the step of anisotropically etching the plurality of bit line structures to remove a portion of a top of at least one of the bit line structures is performed by anisotropically etching the silicon nitride layer of at least one of the bit line structures in the presence of a fluorine-containing compound at a temperature between 10° C. and 200° C. and a pressure between 0.1 and 30 torr.

6. The method according to claim 1, wherein the step of anisotropically etching the plurality of bit line structures is performed by:
forming a resist layer on the cobalt silicide layer, wherein the resist layer fills the space between two adjacent bit line structures;
etching back the resist layer to reveal the silicon nitride layer of the bit line structure;
anisotropically etching the silicon nitride layer of at least one of the bit line structures in the presence of a fluorine-containing compound at a temperature between 10° C. and 200° C. and a pressure between 0.1 and 30 torr; and
removing the remaining resist layer by dry stripping or wet stripping.

7. The method according to claim 5, wherein the fluorine-containing compound is selected from a group consisting of hydrogen fluoride, trifluoromethane, tetrafluoromethane, and sulfur hexafluoride.

8. The method according to claim 1, wherein after the step of performing a chemical mechanical polishing, at least one of the bit line structures has a width at its top that is 20% less than a width at its bottom.

9. The method according to claim 8, wherein after the step of performing a chemical mechanical polishing, at least one of the bit line structures has a width at its top that is 30% less than a width at its bottom.

10. The method according to claim 9, wherein after the step of performing a chemical mechanical polishing, at least one of the bit line structures has a width at its top that is 40% less than a width at its bottom.

11. The method according to claim 1, further comprising performing a post-cleaning operation prior to the step of conformally depositing a titanium nitride layer on the cobalt silicide layer and the plurality of bit line structures.

12. The method according to claim 1, wherein the step of etching the second tungsten layer to form a recess is performed by removing a top corner of the bit line structure, a portion of the titanium nitride layer adjacent to the bit line structure, a portion of the first tungsten layer adjacent to the titanium nitride layer, and a portion of the second tungsten layer atop the first tungsten layer, the titanium nitride layer and the bit line structure.

13. The method according to claim 1, wherein a tilt dry-etching is performed to remove a top corner of the bit line structure.

14. The method according to claim 1, wherein the step of depositing a land pad is performed by spin-coating, sputtering, atomic layer deposition (ALD), atomic layer epitaxy (ALE), atomic layer chemical vapor deposition (ALCVD), low-pressure chemical vapor deposition (LPCVD), physical vapor deposition (PVD), or a combination thereof.

15. A semiconductor structure, comprising:
a substrate having a plurality of bit line contacts and a plurality of carbon-carbon contacts;
a plurality of bit line structures, disposed on a bit line contact and protruding from the substrate;
a polysilicon layer, disposed on the plurality of carbon-carbon contacts of the substrate;
a cobalt silicide layer, disposed on the polysilicon layer, wherein the plurality of bit line structures penetrate through the polysilicon layer and protrude from the cobalt silicide layer;
a titanium nitride layer, conformally disposed on the cobalt silicide layer and the plurality of bit line structures;
a first tungsten layer, disposed on the titanium nitride layer;
a second tungsten layer, disposed on the first tungsten layer; and
a landing pad, disposed in a top corner of the bit line structure and on a portion of the second tungsten layer;
wherein at least one of the bit line structures has a width at its top less than a width at its bottom.

16. The semiconductor structure according to claim 15, wherein at least one of the bit line structures includes a metal nitride layer, a bit line layer, and a hard mask layer sequentially stacked on the substrate.

17. The semiconductor structure according to claim 16, wherein the metal nitride layer is a titanium nitride layer and the hard mask layer is a silicon nitride layer.

18. The semiconductor structure according to claim 15, wherein at least one of the bit line structures has a width at its top that is 20% less than a width at its bottom.

19. The semiconductor structure according to claim 18, wherein at least one of the bit line structures has a width at its top that is 30% less than a width at its bottom.

20. The semiconductor structure according to claim 19, wherein at least one of the bit line structures has a width at its top that is 40% less than a width at its bottom.
